(19) United States
(12) Patent Application Publication
(10) Pub. No.: US 2013/0266725 A1
(43) Pub. Date: Oct. 10, 2013

(54) CERAMIC-SUPPORTED METAL-CONTAINING COMPOSITES FOR RECHARGEABLE OXIDE-ION BATTERY (ROB) CELLS

(71) Applicant: Chun Lu, Sewickley, PA (US)

(72) Inventor: Chun Lu, Sewickley, PA (US)

(21) Appl. No.: 13/441,066

(22) Filed: Apr. 6, 2012

(51) Int. Cl. B05D 5/12; C23C 16/06

(52) U.S. Cl. 427/123; 427/126.2

(57) ABSTRACT

A method for producing a ceramic-supported metal-containing composite (66), useful for rechargeable oxide-ion battery cells, contains the steps of: providing a ceramic substrate (60) and metal-containing material (62); then depositing (64) the metal containing material (62) onto the surface of the ceramic substrate (60).

### BACKGROUND OF THE INVENTION

1. Field

This present invention relates to a method for producing ceramic-supported metal-containing composites, useful for rechargeable oxide-ion battery (ROB) cells, by forming metal-containing material on the surface of a ceramic substrate.

2. Description of Related Art

Electrical energy storage is crucial for the effective proliferation of an electrical economy and for the implementation of many renewable energy technologies. During the past two decades, the demand for the storage of electrical energy has increased significantly in the areas of portable, transportation, load-leveling and central backup applications.

The present electrochemical energy storage systems are simply too costly to penetrate major new markets. Higher performance is required, and environmentally acceptable materials are preferred. Transformational changes in electrical energy storage science and technology are in great demand to allow higher and faster energy storage at lower costs and longer lifetimes necessary for major market enlargement. Most of these changes require new materials and/or innovative concepts, with demonstration of larger redox capacities that react more rapidly and reversibly with cations and/or anions.

Batteries are by far the most common form of storing electrical energy, ranging from: standard every day lead-acid cells; nickel-metal hydride (NIMH) batteries, taught by Kitayama in U.S. Pat. No. 6,399,247 B1; metal-air cells taught by Isenberg in U.S. Pat. No. 4,054,729, to the lithium-ion battery taught by Ohata in U.S. Pat. No. 7,396,612 B2. Most of these latter battery cells require liquid electrolyte systems.

Batteries range in size from button cells used in switches, to megawatt load leveling applications. They are, in general, efficient storage devices, with output energy typically exceeding 90% of input energy, except at the highest power densities.

Rechargeable batteries have evolved over the years from lead-acid through nickel-cadmium and nickel-metal hydride (NiMH) to lithium-ion batteries. NiMH batteries were the initial workhorse for electronic devices such as computers and cell phones, but they have almost been completely displaced from that market by lithium-ion batteries because of the latter's higher energy storage capacity. Today, NiMH technology is the principal battery used in hybrid electric vehicles, but it is likely to be displaced by the higher power energy and now lower cost lithium batteries, if the latter's safety and lifetime can be improved. Of the advanced batteries, lithium-ion is the dominant power source for most rechargeable electronic devices.

What is needed is a dramatically new electrical energy storage device that can easily discharge and charge a high capacity of energy quickly and reversibly, as needed. What is also needed is a device that can operate for years without major maintenance. What is also needed is a device that does not need to operate on natural gas, hydrocarbon fuel or its reformed by-products such as H₂. One possibility is a rechargeable oxide-ion battery (ROB), as set out, for example, in U.S. application Ser. No. 13/167,900, filed Jun. 24, 2011, and U.S. Patent Publication No. 2011/0033769 A1 (Huang et al.).

A ROB essentially is an oxygen-concentration cell, and it comprises a metal electrode, an oxide-ion conductive electrolyte, and an air cathode. The metal electrode undergoes reduction-oxidation cycles during charge and discharge processes for energy storage. The working principles of a rechargeable oxide-ion battery cell 10 are schematically shown in FIG. 1. In discharge mode, oxygen molecules are electrochemically reduced into oxide ions on air electrode 12 by the cathodic reaction of x/2O₂+2xe⁻→xO²⁻. The oxide ions migrate from the air electrode (high oxygen partial pressure side) to the metal electrode (14, low oxygen partial pressure side) through the electrolyte 16 under the driving force of gradient oxygen chemical potential. In principle, there exist two possible reaction mechanisms to oxidize the metal. One of them, solid-state diffusion reaction designated as Path 1, is that oxide ion can directly electrochemically oxidize metal to form metal oxide. The other, gas-phase transport reaction designated as Path 2, involves generation and consumption of gaseous phase oxygen specie. The reactive interface 18, that converts oxide ions into gaseous phase oxygen species, locates in the vicinity of metal electrode-electrolyte interface. The oxide ion can be initially converted to a gaseous oxygen molecule on a metal electrode, and then further reacts with metal via solid-gas phase mechanism to faun metal oxide. In charge mode, the oxygen species, released by reducing metal oxide to metal via electrochemical Path 1 or solid-gas mechanism Path 2, are transported from the metal electrode back to the air electrode.

As one of the key components in a ROB metal electrode, the metal (Me) plays a reservoir role in uptaking or releasing oxygen during discharge-charge cycle via the electrodic reaction of Me+xO²⁻⇄MeOₓ. The Me in a ROB is selected from Ti, V, Cr, Mn, Fe, Co, Ni, Cu, Mo, Y, and W, preferably Mn, Fe, Mo, and W, more preferably Fe. The metal oxidation kinetics, if controlled by bulk diffusion of active species through dense oxide scale, can be depicted by parabolic law of (λw)²=k_{g}t (Equation 1) where λ is weight fraction of oxygen in oxide, w the weight gain per surface area in g/cm², k_{g} the parabolic reaction constant in g²/cm⁴/s, and t the reaction time in s (second). Provided that the surface area of active material is A (cm²/g) and total weight gain of W in gram, then

$$w = \frac{W}{A} . \qquad ( Equation 2 )$$

Combining the above two equations and make derivative W with respect to t, then one yields

$$\frac{d W}{d t} = A \frac{\sqrt{{k}_{g}}}{2 λ} \sqrt[- \frac{1}{2}]{t} \qquad ( Equation 3 )$$

$$\frac{d W}{d t}$$

can then further be mathematically derived into maximum electrical current I (ampere) using the formula of

$$I = \frac{n F}{Z} \frac{d W}{d t} = A \frac{n F}{Z} \frac{\sqrt{{k}_{g}}}{2 λ} \sqrt[- \frac{1}{2}]{t} \qquad ( Equation 4 )$$

where n is the number of electrical charges involved in the oxidation reaction, F the Faraday constant of 96485 coulumb/mol, and Z the formula weight of the oxide. Equation 4 clearly suggests that the maximum electrical current I is proportional to A. Simply speaking, the larger A, the higher I. Clearly, increasing surface area (A) of the active materials emerges as one of leading solutions to enhance overall metal redox reactions and consequently boost cell performance in terms of current during charge-discharge operation for energy storage. Thus, fine iron particles are preferred for ROB application. Unfortunately, directly handling and processing fine metal particles including Fe imposes serious risk due to increasing fire danger with the decreasing size of metal particles. In addition, even if safety measures prudently implemented enable utilization of finer metal powder, for example Fe, the loss of surface area of Fe particles at high temperature may lead to the degradation of cell perfoimance of a ROB over an extended period time of operation. The loss of surface area is the consequence of densification and/or coarsening of the materials driven by minimization of its surface energy of the active material. Therefore, there is an urgent need to develop a method for producing metal-containing materials so that the fine metal structures (e.g. Fe) can be handled at a relatively safe manner despite its fairly microscopic size during cell assembly, and the fine metal structures in the materials possess significant resistance against sintering and consequently preserve its surface area over time at high temperature (600° C.-800° C.).

It is a main object of this invention to provide a method for producing ceramic-supported metal-containing composites for use, generally, in a metal electrode of rechargeable oxide-ion battery (ROB) cells operated in the temperature range of 600° C.-800° C.

### SUMMARY

The above needs for producing ceramic-supported metal-containing composites for a ROB cell are supplied and object accomplished by: (A) providing a ceramic substrate and metal-containing material. The ceramic substrate comprises aluminum oxide, magnesium oxide, calcium oxide, strontium oxide, barium oxide, scandium oxide, titanium oxide, vanadium oxide, chromium oxide, manganese oxide, yttrium oxide, zirconia oxide, niobium oxide, molybdenum oxide, hafnium oxide, tantalum oxide, tungsten oxide, lanthanide oxide, and mixtures thereof. The ceramic substrate is in skeleton form. The skeleton has a porosity of 95 volume percent to 15 volume percent preferably 85 volume percent to 30 volume percent, more preferably 75 volume percent to 50 volume percent. The metal-containing material comprises elemental metal or its compounds; and (B) depositing the metal-containing material on the surface of the ceramic substrate to form a composite where the deposited metal-containing structure is supported by the surface of the ceramic substrate. The deposition technique comprises spray coating, slurry casting, infiltration, impregnation, physical vapor deposition, and chemical vapor deposition. The metal-containing structures comprise iron (Fe) species, and the Fe species contain additives selected from chromium, manganese, cobalt, nickel, copper, zinc, lithium oxide, sodium oxide, potassium oxide, aluminum oxide, magnesium oxide, calcium oxide, strontium oxide, barium oxide, scandium oxide, titanium oxide, vanadium oxide, chromium oxide, manganese oxide, cobalt oxide, nickel oxide, copper oxide, zinc oxide, yttrium oxide, zirconia oxide, niobium oxide, molybdenum oxide, hafnium oxide, tantalum oxide, tungsten oxide, lanthanide oxide, and any combination among them, preferably calcium oxide, strontium oxide, barium oxide, scandium oxide, titanium oxide, yttrium oxide, zirconia oxide, niobium oxide, hafnium oxide, tungsten oxide, lanthanide oxide, more preferably barium oxide, zirconia oxide, and hafnium oxide. The amount of additives is from 0.01 mol % to 50 mol %, preferably 0.1 mol % to 25 mol %, more preferably 1 mol % to 10 mol %. The metal-containing structures have particle size from 0.1 millimeter to 0.000001 millimeter, preferably 0.05 millimeter to 0.00001 millimeter, more preferably 0.01 millimeter to 0.001 millimeter. The coverage of the metal-containing structure on the surface of the ceramic substrate is from 95% to 30%, preferably 85% to 40%, more preferably 75% to 60%. The ratio between the metal-containing structure and the ceramic substrate is from 10 weight percent to 90 weight percent preferably 30 weight percent to 80 weight percent, more preferably 45 weight percent to 70 weight percent.

### BRIEF DESCRIPTION OF THE DRAWINGS

For a better understanding of the invention, reference may be made to the preferred embodiments exemplary of this invention, shown in the accompanying drawings in which:

FIG. 1 illustrates the known working principle of a rechargeable oxide-ion battery (ROB) cell;

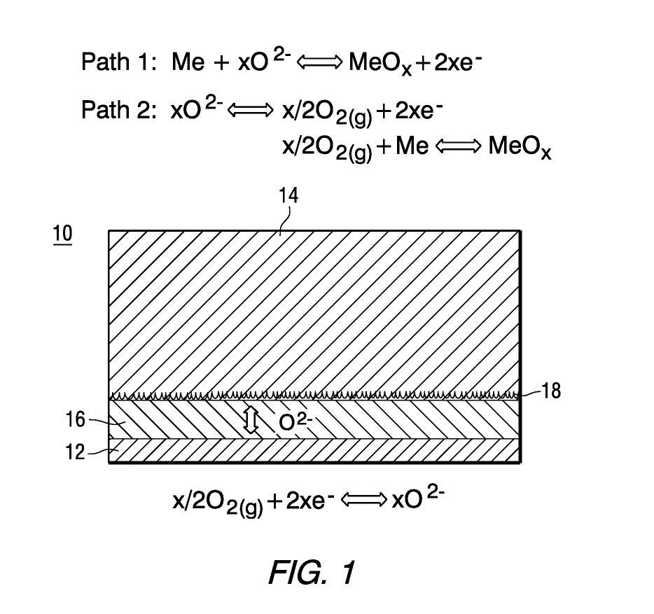

FIG. 2 is a schematic illustration of joining together a planar ROB cell, showing component arrangement, including a metal electrode;

FIG. 3, which best illustrates the invention, is a flow chart of a method for producing ceramic-supported metal-containing composites according to this invention, suitable for ROB cells; and

FIG. 4 is an idealized schematic of metal particles supported by a fibrous skeleton structure.

### DESCRIPTION OF THE PREFERRED EMBODIMENT

The requirements of a ROB cell include:
a) an air electrode cathode for reversible conversion of oxygen into an oxide ion that has two electrical charges;
b) an oxide-ion conductive electrolyte for transporting electrical charge;
c) a metal electrode where electrical charge associated with the oxide-ion is stored or released by an active metal component(s), and for accommodating the volume change associated with a metal redox reaction;
d) a reliable seal separating direct contact between air and active metal; and
e) cost effectiveness.

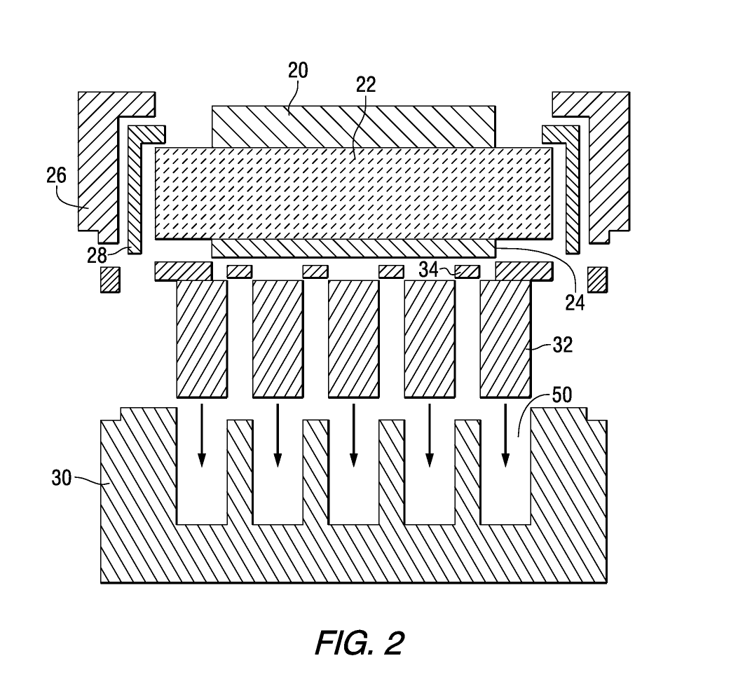

Referring now to FIG. 2, which shows a schematic illustration of joining components of one embodiment of a planar ROB cell including a metal electrode. The top air electrode is shown as 20, while 22 shows a sandwiched ceramic middle electrolyte, and 24 shows the bottom metal electrode. Components 20, 22 and 24 together form a membrane assembly. FIG. 2 shows a surrounding metallic frame 26. A seal 28 connects the membrane assembly to the frame 26. A metal housing structure 30 is shown, where active material 32 will fill the metal housing pockets, holes 50. An electrical current connector 34 is shown between the metal housing structure 30 and the bottom metal electrode 24. Other unlabeled seals are also shown.

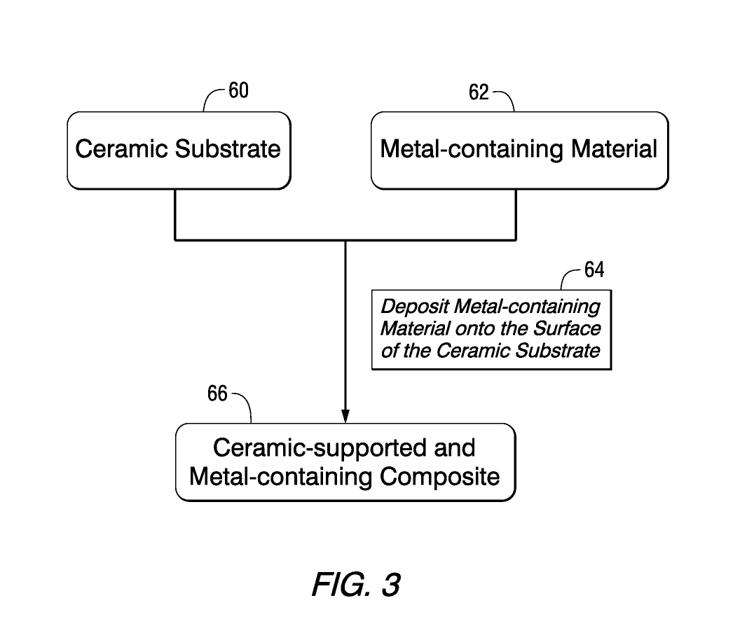

The disclosed invention is described in FIG. 3, which illustrates a flow chart of a method for producing ceramic-supported metal-containing composites. It starts with providing a ceramic substrate 60 and metal-containing material 62. The ceramic substrate is selected from the group consisting of aluminum oxide, magnesium oxide, calcium oxide, strontium oxide, barium oxide, scandium oxide, titanium oxide, vanadium oxide, chromium oxide, manganese oxide, yttrium oxide, zirconia oxide, niobium oxide, molybdenum oxide, hafnium oxide, tantalum oxide, tungsten oxide, lanthanide oxide, and mixtures thereof, preferably aluminum oxide, barium oxide, zirconia oxide, hafnium oxide and mixtures thereof. The ceramic substrate is in skeleton form. The skeleton has a porosity of 95 volume percent to 15 volume percent, preferably 85 volume percent to 30 volume percent, more preferably 75 volume percent to 50 volume percent. The metal-containing material comprises elemental metal or its compounds. Then metal-containing material is deposited 64 on the surface of the ceramic substrate to form a composite 66 where the deposited metal-containing structure is supported by the surface of the ceramic substrate. The deposition technique comprises spray coating, slurry casting, infiltration, impregnation, physical vapor deposition, and chemical vapor deposition. The metal-containing structures comprise iron (Fe) species, and the Fe species contain additives selected from the group consisting of chromium, manganese, cobalt, nickel, copper, zinc, lithium oxide, sodium oxide, potassium oxide, aluminum oxide, magnesium oxide, calcium oxide, strontium oxide, barium oxide, scandium oxide, titanium oxide, vanadium oxide, chromium oxide, manganese oxide, cobalt oxide, nickel oxide, copper oxide, zinc oxide, yttrium oxide, zirconia oxide, niobium oxide, molybdenum oxide, hafnium oxide, tantalum oxide, tungsten oxide, lanthanide oxide, and mixtures thereof, preferably calcium oxide, strontium oxide, barium oxide, scandium oxide, titanium oxide, yttrium oxide, zirconia oxide, niobium oxide, hafnium oxide, tungsten oxide, lanthanide oxide, more preferably barium oxide, zirconia oxide, and hafnium oxide. The amount of additives is from 0.01 mol % to 50 mol %, preferably 0.1 mol % to 25 mol %, more preferably 1 mol % to 10 mol %. The metal-containing structures have average size from 0.1 millimeter to 0.000001 millimeter, preferably 0.05 millimeter to 0.00001 millimeter, more preferably 0.01 millimeter to 0.001 millimeter. The coverage of the metal-containing structure on the surface of the ceramic substrate is from 95% to 30%, preferably 85% to 40%, more preferably 75% to 60%. The ratio between the metal-containing structure and the ceramic substrate is from 10 weight percent to 90 weight percent, preferably 30 weight percent to 80 weight percent, more preferably 45 weight percent to 70 weight percent.

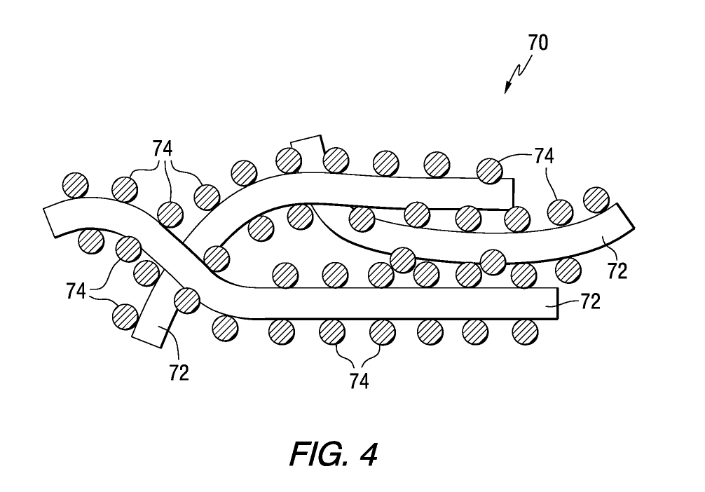

FIG. 4 shows an idealized schematic of the ceramic-supported metal-containing composite, showing interwoven porous skeleton structure 70 wherein interlocking ceramic fibers 72 supports discrete metal (e.g. Fe) particles 74 on the surface of fibers within the skeleton.

### EXAMPLE

As an illustration of the invented processing technique, an alumina-supported Fe-containing composite was prepared with an impregnation technique. 151.5 grams iron nitrate (FeNO₃) was dissolved into distilled water to form 250 milliliter precursor solution. A porous alumina fiber skeleton with 90% porosity was soaked with the aqueous iron nitrate (FeNO₃) solution at ambient condition. Then the FeNO₃-impregnated skeleton was dried and heated to 450° C. for thirty minutes in air using a ramping rate of 5° C./min. The FeNO₃ was decomposed into iron oxide (Fe₂O₃) during the heat treatment. The soaking-drying-heating steps were repeated five times to form the alumina-supported Fe-containing composite where the ratio of Fe₂O₃:Al₂O₃ was approximately 45:65 in weight. The composite was treated in a dry 95% nitrogen—5% hydrogen gas at 800° C. for six hours to reduce Fe₂O₃ structures into elemental Fe particles. A cross-sectional scanning electron microscope image revealed iron particles on the surface of the alumina fibers.

While specific embodiments of the invention have been described in detail, it will be appreciated by those skilled in the art that various modifications and alternatives to those details could be developed in light of the overall teachings of the disclosure. Accordingly, the particular embodiments disclosed are meant to be illustrative only and not limiting as to the scope of the invention which is to be given the full breadth of the appended claims and any and all equivalents thereof.

What is claimed is:

1. A method of manufacturing a ceramic-supported metal-containing composite useful for rechargeable oxide-ion battery cells comprising the steps of:
(a) providing a ceramic substrate having an interlocking skeleton structure;
(b) providing an iron metal-containing material; and
(c) depositing the metal-containing material on the surface of the ceramic substrate to form a composite, where the deposited metal-containing material is supported by the surface of the ceramic substrate and has a particle size from 0.1 millimeter to 0.000001 millimeter and covers 95% to 30% of the ceramic substrate surface.

2. The method of claim 1, wherein the ceramic substrate is selected from the group consisting of aluminum oxide, magnesium oxide, calcium oxide, strontium oxide, barium oxide, scandium oxide, titanium oxide, vanadium oxide, chromium oxide, manganese oxide, yttrium oxide, zirconia oxide, niobium oxide, molybdenum oxide, hafnium oxide, tantalum oxide, tungsten oxide, lanthanide oxide, and any combination among them, preferably aluminum oxide, calcium oxide, strontium oxide, barium oxide, scandium oxide, titanium oxide, yttrium oxide, zirconia oxide, niobium oxide, hafnium oxide, tungsten oxide, lanthanide oxide, and mixtures thereof.

3. The method of claim 1, wherein the ceramic substrate is selected from the group consisting of aluminum oxide, barium oxide, zirconia oxide, hafnium oxide, and mixtures thereof.

4. The method of claim 1, wherein the skeleton of claim 1 has a porosity of 85 volume percent to 30 volume percent.

5. The method of claim 1, wherein the metal-containing material comprises elemental metal or its compounds.

6. The method of claim 1, wherein the deposition process of claim 1 is selected from the group consisting of spray coating, slurry casting, infiltration, impregnation, physical vapor deposition, and chemical vapor deposition.

7. The method of claim 1, wherein the iron containing material of claim 1 contain additives selected from the group consisting of chromium, manganese, cobalt, nickel, copper, zinc, lithium oxide, sodium oxide, potassium oxide, aluminum oxide, magnesium oxide, calcium oxide, strontium oxide, barium oxide, scandium oxide, titanium oxide, vanadium oxide, chromium oxide, manganese oxide, cobalt oxide, nickel oxide, copper oxide, zinc oxide, yttrium oxide, zirconia oxide, niobium oxide, molybdenum oxide, hafnium oxide, tantalum oxide, tungsten oxide, lanthanide oxide, and their mixtures.

8. The method of claim 7, wherein the amount of additives is from 0.01 mol % to 50 mol %.

9. The method of claim 7, wherein the amount of additives is from 0.1 mol % to 25 mol %.

10. The method of claim 7, wherein the metal-containing material has a particle size from 0.05 millimeter to 0.00001 millimeter.

11. The method of claim 7, wherein the coverage of the metal-containing material on the surface of the ceramic surface is from 85% to 40%, and the ratio between the metal-containing material and the ceramic substrate is from 10 weight percent to 90 weight percent.
